(19) United States
(12) Patent Application Publication
(10) Pub. No.: US 2009/0051022 A1
(43) Pub. Date: Feb. 26, 2009

(54) LEAD FRAME STRUCTURE

(75) Inventor: Kouji ANDOH, Motosu-city (JP)

Correspondence Address: NIXON & VANDERHYE, PC, 901 NORTH GLEBE ROAD, 11TH FLOOR, ARLINGTON, VA, 22203, US

(73) Assignee: DENSO CORPORATION, Kariya-city (JP)

(21) Appl. No.: 12/196,506

(22) Filed: Aug. 22, 2008

(30) Foreign Application Priority Data
Aug. 24, 2007 (JP) 2007-218242

(51) Int. Cl. H01L 23/495

(52) U.S. Cl. 257/677; 257/E23.031

(57) ABSTRACT

A lead frame structure includes a lead frame, a partial plated portion, a semiconductor element, a Pb-free solder and a mold resin. The partial plated portion is formed on a part of a surface of the lead frame. The partial plated portion is made of a noble metal. The semiconductor element is bonded with the partial plated portion through a Pb-free solder and is electrically connected to the lead frame through the Pb-free solder and the partial plated portion. The mold resin encloses the semiconductor element and the lead frame other than a coupling portion, which is to be electrically coupled to an external device.

### CROSS REFERENCE TO RELATED APPLICATION

This application is based on Japanese Patent Application No. 2007-218242 filed on Aug. 24, 2007, the disclosure of which is incorporated herein by reference.

### FIELD OF THE INVENTION

The present invention relates to a lead fame structure in which a semiconductor element is mounted to a lead frame with a lead-free solder.

### BACKGROUND OF THE INVENTION

It is known to directly mount a semiconductor element of a bare chip to a lead frame by soldering so as to improve heat radiation of the semiconductor element through the lead frame. Also, it is known to embed the semiconductor element and a soldered portion of the lead frame with a molded resin, so as to reduce a thermal stress to the soldered portion. For example, Japanese Unexamined Patent Application Publication No. 2004-119944 describes a semiconductor module in which a semiconductor chip is directly bonded to a board with a lead-free solder (hereinafter, Pb-free solder).

### SUMMARY OF THE INVENTION

Recently, the Pb-free solder without containing lead (Pb) has been used to aware of environmental issues. However, wettability of the Pb-free solder to the lead frame is likely to be insufficient, resulting in a defect of solder wettability and an increase in a void content of the solder. As such, it will be difficult to maintain reliability of soldering.

The present invention is made in view of the foregoing issue, and an object of the present invention is to provide a lead frame structure capable of improving reliability of soldering by enhancing wettability of a Pb-free solder.

According to an aspect of the present invention, a lead frame structure includes a lead frame, a partial plated portion, a semiconductor element, a Pb-free solder and a mold resin. The lead frame serves as a heat sink and a terminal for achieving an electric connection with an external device. The partial plated portion is disposed on a part of a surface of the lead frame and is made of a noble metal. The semiconductor element is bonded with the partial plated portion through the Pb-free solder and is electrically connected to the lead frame through the Pb-free solder and the partial plated portion. The mold resin encloses the semiconductor element and the lead frame other than a coupling portion of the lead frame, which is to be electrically coupled to an external device.

In this construction, the Pb-free solder is bonded with the partial plated portion made of a noble metal, solder wettability improves, as compared with a case where the Pb-free solder is bonded with the lead frame. As such, a defect of solder wettability and an increase in a void content will be reduced. Accordingly, reliability of soldering improves.

### BRIEF DESCRIPTION OF THE DRAWINGS

Other objects, features and advantages of the present invention will become more apparent from the following detailed description made with reference to the accompanying drawings, in which like parts are designated by like reference numerals and in which:

FIG. 1A is a schematic layout of a lead frame structure according to a first embodiment of the present invention;

FIG. 1B is a cross-sectional view taken along a line IB-IB in FIG. 1A;

FIG. 2A is a schematic layout of a lead frame structure according to a second embodiment of the present invention; and

FIG. 2B is a cross-sectional view taken along a line IIB-IIB in FIG. 2A.

### DETAILED DESCRIPTION OF EXEMPLARY EMBODIMENTS

### First Embodiment

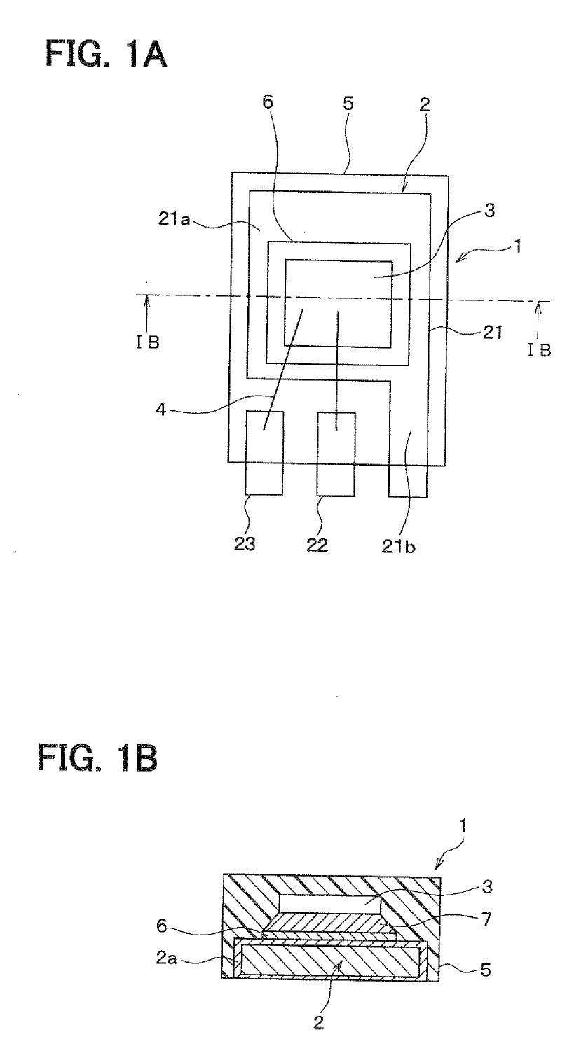

A first embodiment of the present invention will now be described with reference to FIGS. 1A and 1B.

A lead frame structure 1 of the present embodiment is, for example, used to control engine devices. The lead frame structure 1 includes a lead frame 2, a semiconductor element 3, bonding wires 4, a mold resin 5 and the like.

The lead frame 2 serves as a wiring member for achieving an electric connection with at least one external device and also serves as a heat sink for radiating heat generated from the semiconductor element 3. For example, the lead frame 2 is formed by stamping a metal plate and applying a Ni plate 2a on a surface of the stamped metal plate. The metal plate is, for example, made of Cu, Fe, Mo, alloy or the like.

The lead frame 2 includes a first frame portion 21, a second frame portion 22 and a third frame portion 23. The first frame portion 21 has a seating surface to which the semiconductor element 3 is mounted. The second frame portion 22 and the third frame portion 23 are separate from the first frame portion 21, but are electrically coupled to predetermined portions of the semiconductor element 3.

The first frame portion 21 has a land portion 21a and a terminal portion 21b. The land portion 21a provides the seating surface to which the semiconductor element 3 is mounted. The land portion 21a, for example, has a rectangular shape. The land portion 21a is larger than the semiconductor element 3. The terminal portion 21b extends from a corner of the land portion 21a in a direction parallel to an arrangement direction (e.g., up and down direction in FIG. 1) of the second and third frame portions 22, 23 relative to the first frame portion 21.

The second frame portion 22 and the third frame portion 23 are spaced from the land portion 21a by a predetermined distance. The terminal portion 21b, the second frame portion 22 and the third frame portion 23 are arranged at equal intervals in a direction perpendicular to the arrangement direction.

A partial plated portion 6 is formed on a part of the seating surface of the land portion 21a, the part where the semiconductor element 3 is mounted. The partial plated portion 6 is formed of a noble metal, such as Ag (silver), Pt (platinum), Au (gold) or the like. The semiconductor element 3 is bonded with a surface of the partial plated portion 6 through a Pb-free solder 7.

The semiconductor element 3 corresponds to an electronic device that generates heat and needs a heat radiation structure, as a heating element. For example, the semiconductor element 3 has electrodes on front and rear surfaces, and includes elements that allows electric currents between the electrodes of the front surface and the electrodes of the rear surface, like an IGBT and a vertical power MOSFET.

The electrodes on the rear surface of the semiconductor element 3 are electrically and physically connected to the first frame portion 21 through the Pb-free solder 7 and the partial plated portion 6. The electrodes on the front surface of the semiconductor element 3 are electrically coupled to the second frame portion 22 and the third frame portion 23 through the bonding wires 4.

The Pb-free solder 7 is a soldering material that contains Sn (tin) as a main component, but does not contain Pb (lead). For example, the soldering material consists of Sn—Cu—Ni, Sn—Ag—Cu, or the like.

The mold resin 5 is molded to enclose the semiconductor element 3, the bonding wires 4 and the lead frame 2 other than coupling portions of the first to third frame portions 21, 22, 23, so that a thermal stress to the soldering portion is reduced. The coupling portions of the lead frame 2 are exposed from the mold resin 5 and are capable of being coupled to external devices.

The lead frame structure 1 configured as above is formed in the following manner, for example. The metal plate is stamped into a predetermined shape. The Ni plate 2a is formed on the surface of the metal plate. The Ni plate 2a is, for example, formed by electrolyte Ni plating, electroless Ni plating, electroless Ni—P plating or the like. As such, the lead frame 2 is formed.

Then, the partial plated portion 6 of the noble metal is formed on the seating surface of the first frame portion 21 with a size larger than the semiconductor element 3. The semiconductor element 3 is electrically and physically connected to a surface of the partial plated portion 6 through the Pb-free solder 7. Then, the mold resin 5 is applied to enclose the necessary portions of the lead frame 2 and the semiconductor element 3.

In this structure, the Pb-free solder 7 is not directly bonded with the lead frame 2. Instead, the Pb-free solder 7 is bonded with the partial plated portion 6, which is made of the noble metal having wettability relative to the Pb-free solder 7 higher than that of the Ni plate 2a formed on the surface of the lead frame 2, in a step such as solder die bonding, reflowing or the like. Therefore, the wettability of the Pb-free solder 7 is enhanced. As such, a defect of solder wettability and an increase in a void content are reduced. Accordingly, reliability of soldering improves.

In the present embodiment, for example, the semiconductor element 3 has a rectangular shape. The partial plated portion 6 has the similar shape. The semiconductor element 3 is mounted such that each side is opposed to or substantially parallel to a corresponding side of the partial plated portion 6.

A region or an area where the partial plated portion 6 is formed is not particularly limited as long as the semiconductor element 3 is easily mounted with the Pb-free solder 7. For example, the size of the partial plated portion 6 is equal to or larger than the size of the semiconductor element 3 so as to allow a displacement when the semiconductor element 3 is mounted on the partial plated portion 6.

The semiconductor element 3 and the Pb-free solder 7 are bonded with each other in the step such as solder die bonding, reflowing or the like. If the area or size of the partial plated portion 6 is large more than necessary, the semiconductor element 3 will be slid and a mounting position will be displaced. Therefore, it is preferable that the partial plated portion 6 is slightly larger than the semiconductor element 3. For example, the partial plated portion 6 is larger than the semiconductor element 3 such that a predetermined distance, such as approximately 1 mm, is maintained between each side of the semiconductor element 3 and the corresponding side of the partial plated portion 6.

The partial plated portion 6 can have any thickness. In fact, the noble metal such as Ag is easily soluble to the Pb-free solder 7. If the Ag is contained in the Pb-free solder 7 more than necessary, Ag—Sn alloy is formed. As a result the strength of the Pb-free solder 7 is likely to be deteriorated, reducing reliability of the Pb-free solder 7. Therefore, the thickness of the partial plated portion 6 is preferably equal to or less than 6 μm. For example, the thickness of the partial plated portion 6 is approximately 5 μm.

In the present embodiment, the partial plated portion 6 of the noble metal is formed on the surface of the lead frame 2, and the semiconductor element 3 is mounted to the lead frame 2 through the Pb-free solder 7 and the partial plated portion 6. Since the Pb-free solder 7 is bonded with the partial plated portion 6, the solder wettability is improved, as compared with the case where the Pb-free solder 7 is bonded with the lead frame 2. As such, a defect of solder wettability and an increase in a void content are reduced. Accordingly, the reliability of soldering improves.

### Second Embodiment

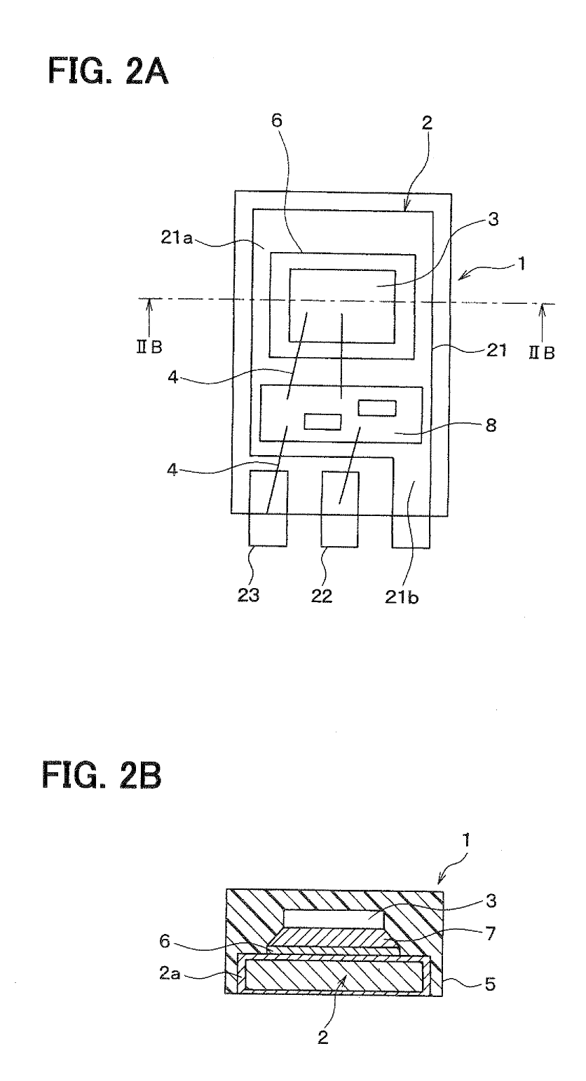

A second embodiment of the present invention will now be described with reference to FIGS. 2A and 2B. A lead frame structure 1 of the present embodiment has a circuit board (control board) 8, in addition to the lead frame structure 1 of the first embodiment. Hereinafter, like components are denoted by like reference numerals, and a description thereof is omitted.

As shown in FIG. 2A, the circuit board 8 on which processing circuits are formed is mounted on the seating surface of the first frame portion 21 of the lead frame 2. The semiconductor element 3, the circuit board 8 and the like are embedded in the mold resin 5.

The circuit board 8 is, for example, a ceramic board, and is bonded with the first frame portion 21 through an adhesive and the like. Respective portions of the semiconductor element 3 are coupled to corresponding portion of the circuit board 8 through the bonding wires 4. Further, respective portions of the circuit board 8 are coupled to corresponding portions of the second and third frame portions 22, 23 through the bonding wires 4. As such, the electric connections of the semiconductor element 3 to the external devices can be achieved.

Also in the lead frame structure 1 of the present embodiment, the partial plated portion 6 is formed on the seating surface of the first frame portion 21 and the semiconductor element 3 is mounted to the lead frame 2 through the Pb-free solder 7 and the partial plated portion 6. Accordingly, the similar effects as the first embodiment will be provided in the present embodiment.

### Other Embodiments

Exemplary shape and material of the lead frame 2, the semiconductor element 3 and the circuit board 8 are discussed as above. However, the shape and the material of the lead frame 2, the semiconductor element 3 and the circuit board 8 may be modified.

Additional advantages and modifications will readily occur to those skilled in the art. The invention in its broader term is therefore not limited to the specific details, representative apparatus, and illustrative examples shown and described.

What is claimed is:

1. A lead frame structure comprising:
a lead frame having a surface;
a partial plated portion disposed on a part of the surface of the lead frame, the partial plated portion made of a noble metal;
a semiconductor element mounted to the partial plated portion;
a lead-free solder disposed between the partial plated portion and the semiconductor element; and
a mold resin enclosing the semiconductor element and the lead frame other than a coupling portion of the lead frame, the coupling portion being capable of being electrically coupled to an external device, wherein
the semiconductor element is bonded with the partial plated portion through the lead-free solder and is electrically coupled to the lead frame through the lead-free solder and the partial plated portion.

2. The lead frame structure according to claim 1, wherein
the noble metal of the partial plated portion has a wettability with respect to the lead-free solder higher than that of a material of the lead frame on a periphery of the partial plated portion.

3. The lead frame structure according to claim 1, wherein
the lead frame has a nickel plated portion on a periphery of the partial plated portion.

4. The lead frame structure according to claim 1, wherein
the partial plated portion has a size equal to or greater than a size of the semiconductor element.

5. The lead frame structure according to claim 4, wherein
the semiconductor element has a rectangular shape,
the partial plated portion has a rectangular shape, and
the semiconductor element is mounted to the partial plated portion such that each side of the semiconductor element is substantially parallel to a corresponding side of the partial plated portion and each side of the semiconductor element is separated from the corresponding side of the semiconductor element by a predetermined distance.

6. The lead frame structure according to claim 1, wherein
the partial plated portion is formed of one of silver, platinum, and gold.

7. The lead frame structure according to claim 1, wherein
the partial plated portion has a thickness equal to or less than 6 μm.

8. The lead frame structure according to claim 1, wherein
the lead frame includes at least a first frame portion and a second frame portion, and the surface is included in the first frame portion.

9. The lead frame structure according to claim 1, further comprising:
a circuit board bonded with the surface of the lead frame and electrically coupled to the semiconductor element through a bonding wire.
